(19) United States
(12) Patent Application Publication
(10) Pub. No.: US 2008/0210923 A1
(43) Pub. Date: Sep. 4, 2008

(54) SEMICONDUCTOR DEVICE AND METHOD OF MANUFACTURING THE SAME

(75) Inventor: Natsuki Sato, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 11/845,226

(22) Filed: Aug. 27, 2007

(30) Foreign Application Priority Data
Aug. 25, 2006 (JP) 2006-228723

(51) Int. Cl. H01L 45/00

(52) U.S. Cl. 257/4; 438/54; 257/E45.002

(57) ABSTRACT

In a semiconductor device including a heater electrode formed in a contact hole formed in an interlayer insulation film to expose a lower electrode, the heater electrode includes at least three heater electrode layers which are successively laminated and successively increased in specific resistivity in a direction from the lower electrode towards a phase change film in this order. The interlayer insulation film is formed on a semiconductor substrate to cover the lower electrode. The phase change film is formed in contact with an upper surface of the heater electrode. An upper electrode is formed on an upper surface of the phase change film.

This application is based upon and claims the benefit of priority from Japanese patent application No. 2006-228723, filed on Aug. 25, 2006, the disclosure of which is incorporated herein in its entirety by reference.

### BACKGROUND OF THE INVENTION

This invention relates to a semiconductor device and a method of manufacturing the same and, in particular, to a semiconductor device having a nonvolatile memory using a phase change material and a method of manufacturing the same.

A semiconductor memory for use in a semiconductor device is categorized into a volatile memory which loses memory information when power supply is turned off and a nonvolatile memory which retains memory information even when power supply is turned off. For example, the volatile memory is a DRAM (Dynamic Random Access Memory) or a SRAM (Static Random Access Memory) while the nonvolatile memory is an EEPROM (Electrically Erasable Programmable Read Only Memory) or a flash memory. In a recent mobile data terminal, for the purpose of miniaturization and power saving, use is often made of the flash memory which retains memory information even when power supply is turned off.

Recently, however, in order to achieve further miniaturization and power saving, attention is focused upon a phase change memory using a phase change material. The phase change memory is a nonvolatile memory in which two different crystal states, i.e., an amorphous state and a crystalline state, of the phase change material are used as memory information. Specifically, the phase change material is switched between the amorphous state having a high resistance value and the crystalline state having a low resistance value to represent memory information of “1” or “0”. As the above-mentioned phase change material, a chalcogenide material is used.

In the phase change memory, a rewriting operation is carried out in the following manner. The phase change material is supplied with a sufficient amount of Joule heat to be melted. Thereafter, the phase change material is rapidly cooled to be turned into an amorphous state (reset state) having a high resistance. Alternatively, the phase change material is supplied with a smaller amount of Joule heat and then slowly cooled to be turned into a crystalline state (set state) having a low resistance. The amount of heat to be supplied and a cooling rate are controlled by an electric current value and a length (application time) of a pulse applied to the phase change material. Thus, the rewriting operation as the memory is carried out by switching the phase change material between the different crystal states to change a resistance value. A reading operation of the phase change memory is carried out by utilizing the fact that the value of a flowing electric current is different depending on the amorphous state or the crystalline state of the phase change material.

FIG. 1 is a partial sectional view of a related phase change memory cell. On a surface of a semiconductor substrate 100a, a transistor is formed which has a gate electrode 6a and diffusion layer regions 7a and 8a. On the diffusion layer region 8a, a contact plug 9a and a constant potential wiring 10a are successively formed. Thereafter, an interlayer insulation film 5b is formed. On the diffusion layer region 7a, a lower electrode 1b is formed in a hole bored through the interlayer insulation film 5b. Furthermore, another interlayer insulation film 5a is formed. On the lower electrode 1b, a heater electrode 1a is formed in another hole bored through the interlayer insulation film 5a. A phase change film 3a is formed so as to connect the heater electrode 1a. On the phase change film 3a, an upper electrode 4a is formed. Thus, in the related phase change memory cell, the lower electrode 1b and the heater electrode 1a are individually formed on the interlayer insulation films 5b and 5a which constitute different layers.

By Joule heat generated when an electric voltage is applied between the lower electrode 1b and the upper electrode 4a, the heater electrode 1a produces heat, so that the crystal state of the phase change film 3a is switched. By switching the crystal state of the phase change film 3a, an electric resistance of the phase change film 3a is changed. An area of the phase change film 3a where the crystal state is switched is represented as a phase change region 2a. In order to switch the crystal state of the phase change film 3a, a temperature not lower than about 600° C. is required. However, by a limited amount of electric current, only a limited area of the phase change film 3a can be heated to a high temperature not lower than 600° C. Therefore, as illustrated in the figure, the phase change region 2a of the phase change film 3a is an area around a contact surface between the heater electrode 1a and the phase change film 3a.

Thus, in order to appropriately heat the phase change film 3a, the heater electrode 1a is made of a material having an appropriate resistance value, such as titanium silicon nitride or tantalum nitride. In order to resistively heat the phase change film, the resistance value of the heater electrode must be optimized. Thus, in the phase change memory, optimization of the resistance value of the heater electrode is an important object to be achieved. Such a heater electrode is described in, for example, Japanese Unexamined Patent Application Publication (JP-A) No. 2006-510218. In the publication, a lower electrode is formed in a contact hole in an interlayer insulation film and an upper part of the lower electrode is dented by etching to form a recessed area and a heater electrode is formed therein.

### SUMMARY OF THE INVENTION

As described above, upon rewriting the phase change memory, it is necessary to supply the heater electrode with an electric current to produce heat so that the phase change region is heated to a temperature not lower than 600° C. In order to efficiently heat the phase change region to a high temperature with a minimum amount of electric current, optimization of the resistance value of the heater electrode is desired.

It is therefore an object of the present invention to provide a semiconductor device having a phase change memory which can be efficiently heated with a minimum amount of electric current by a heater electrode having an optimum resistance value.

It is another object of the present invention to provide a method of manufacturing a semiconductor device which is easily mass-produced and which has a phase change memory stably operable.

In order to achieve the above-mentioned objects, the present application basically adopts the following techniques. It will readily be understood that the present application also encompasses applied techniques as various modifications without departing from the scope of the present invention.

Semiconductor devices according to this invention and methods according to this invention are as follows:

(1) A semiconductor device comprising:

an interlayer insulation film formed on a semiconductor substrate to cover a lower electrode;

a heater electrode formed in a contact hole formed in the interlayer insulation film to expose the lower electrode;

a phase change film formed in contact with an upper surface of the heater electrode; and

an upper electrode formed on an upper surface of the phase change film;

the heater electrode having a specific resistivity gradually increased in a direction from the lower electrode towards the phase change film.

(2) The semiconductor device as described in the above-mentioned (1), wherein the heater electrode comprises at least three heater electrode layers which are successively laminated and successively increased in specific resistivity in a direction from the lower electrode towards the phase change film in this order.

(3) The semiconductor device as described in the above-mentioned (2), wherein each of the heater electrode layers comprises any one of TiN (titanium nitride), TiSiN (titanium silicon nitride), TiAlN (titanium aluminum nitride), C (carbon), CN (carbon nitride), MoN (molybdenum nitride), TaN (tantalum nitride), PtIr (platinum iridium), TiCN (titanium carbon nitride), and TiSiC (titanium silicon carbide).

(4) The semiconductor device as described in the above-mentioned (1), wherein the phase change film comprises any one of germanium (Ge), antimony (Sb), tellurium (Te), selenium (Se), gallium (Ga), and indium (In).

(5) The semiconductor device as described in the above-mentioned (1), wherein the lower electrode is one of diffusion layers forming a memory cell transistor.

(6) The semiconductor device as described in the above-mentioned (5), wherein the upper electrode is connected to a bit line, another diffusion layer of the memory cell transistor being connected to a constant potential wiring.

(7) A semiconductor device comprising:

a diffusion layer formed in a semiconductor substrate;

an interlayer insulation film formed on the semiconductor substrate to cover the diffusion layer;

a heater electrode formed in a contact hole formed in the interlayer insulation film to expose the diffusion layer;

a phase change film formed in contact with an upper surface of the heater electrode; and

an upper electrode formed on an upper surface of the phase change film;

the heater electrode being formed in the contact hole for electrically connecting the diffusion layer and the phase change film.

(8) The semiconductor device C wherein the heater electrode comprises at least three heater electrode layers which are successively laminated and successively increased in specific resistivity in a direction from the diffusion layer towards the phase change film in this order.

(9) A method of manufacturing a semiconductor device, comprising the steps of:

depositing an interlayer insulation film to cover a lower electrode;

forming a contact hole in the interlayer insulation film to expose the lower electrode;

forming a heater electrode in the contact;

depositing a phase change film in contact with an upper surface of the heater electrode; and

forming an upper electrode on an upper surface of the phase change film;

wherein the step of forming the heater electrode comprises the step of forming at least three heater electrode layers which are successively laminated in the contact hole and successively increased in specific resistivity in a direction from the lower electrode towards the phase change film in this order.

(10) The method as described in the above-mentioned (9), wherein a top one of the heater electrode layers has the specific resistivity equal to or greater than 1000 μΩ·cm.

(11) The method as described in the above-mentioned (9), wherein a top one of the heater electrode layers comprises a metal compound containing a metal, the metal compound having the specific resistivity equal to or greater than 100 times that of the metal.

(12) The method as described in the above-mentioned (9), wherein each of the heater electrode layers comprises any one of TiN (titanium nitride), TiSiN (titanium silicon nitride), TiAlN (titanium aluminum nitride), C (carbon), ON (carbon nitride), MoN (molybdenum nitride), TaN (tantalum nitride), PtIr (platinum iridium), TiCN (titanium carbon nitride), and TiSiC (titanium silicon carbide).

(13) The method as described in the above-mentioned (9), wherein the step of forming the heater electrode layers is executed using MOCVD (Metal Organic Chemical Vapor Deposition).

(14) The method as described in the above-mentioned (13), wherein the step of forming the heater electrode further comprises the step of carrying out treatment for each of the heater electrode layers after each of the heater electrode layers is formed by using the MOCVD.

(15) The method as described in the above-mentioned (14), wherein the specific resistivity of each of the heater electrode layers is changed by controlling a treatment time in the step of carrying out the treatment for each of the heater electrode layers.

(16) The method as described in the above-mentioned (9), further comprising the step of further increasing an upper surface of a top one of the heater electrode layers in specific resistivity by ion-implantation of any one of oxygen, nitrogen, carbon, and silicon.

(17) The method as described in the above-mentioned (11), further comprising the step of further increasing an upper surface of a top one of the heater electrode layers in specific resistivity by using any one of thermal oxidation, plasma oxidation, and plasma nitridation.

The phase change memory in the semiconductor device according to the present invention has a heater electrode comprising at least three heater electrode layers and formed in a contact hole formed in an interlayer insulation film on a lower electrode. At least three heater electrode layers successively laminated in a direction from the lower electrode towards the phase change film have specific resistivity values successively increased in this order. A top one of the heater electrode layers adjacent to the phase change film has the highest specific resistivity and can produce heat to a high temperature with a small amount of electric current. Since a rewriting operation can be performed with a small amount of electric current, a cell transistor can be reduced in size to thereby reduce a cell size. Thus, a semiconductor device having a high-capacity phase change memory can be obtained.

Furthermore, the phase change memory in the semiconductor device according to the present invention has a structure wherein the heater electrode is directly formed on the lower electrode which is one of diffusion layers of a memory cell transistor and wherein the phase change film is formed on the heater electrode. With this structure, it is unnecessary to form the lower electrode of a contact plug. As a result, the steps for forming the interlayer insulation film and for forming the contact plug for use in the lower electrode and other steps associated with the steps can be eliminated. Thus, it is possible to simplify the manufacturing process of the semiconductor device and to realize mass production of the semiconductor devices.

### BRIEF DESCRIPTION OF THE DRAWING

FIG. 1 is a partial sectional view of a related phase change memory cell;

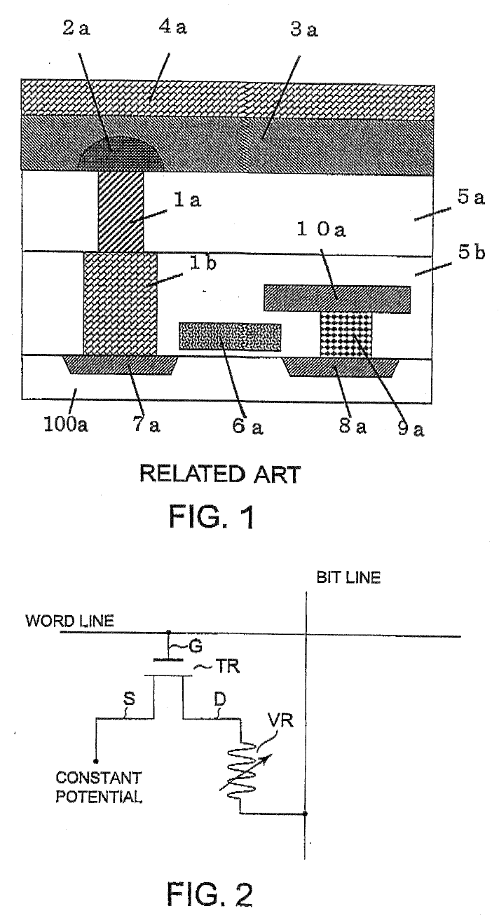

FIG. 2 is a circuit diagram of a phase change memory cell for describing the present invention;

FIGS. 3, 4, 5A, 5B, and 6 are sectional views for describing a production process of a phase change memory cell having a heater electrode structure according to the present invention;

FIGS. 7A and 7B are views for describing conversion from electrode films in a cylindrical shape into electrode layers having equivalent specific resistivities;

FIG. 8 is a sectional view of a phase change memory cell having another heater electrode structure according to the present invention; and

FIG. 9 is a sectional view of a phase change memory cell having still another heater electrode structure according to the present invention.

### DESCRIPTION OF THE PREFERRED EMBODIMENT

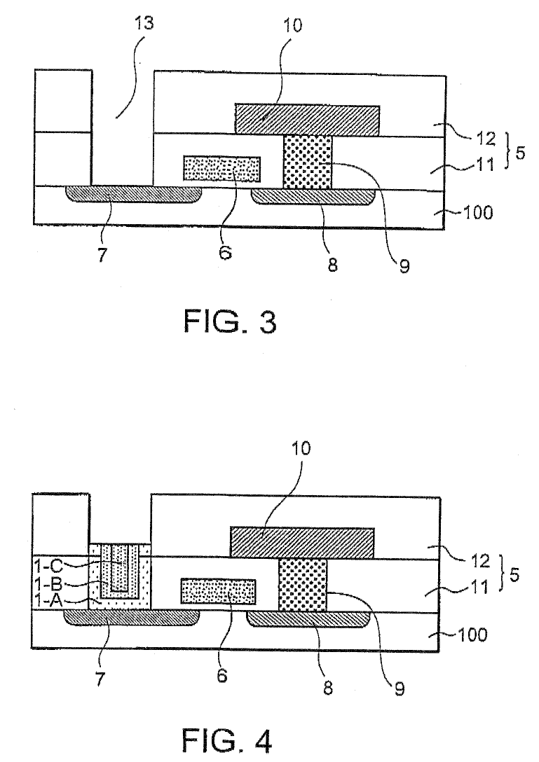

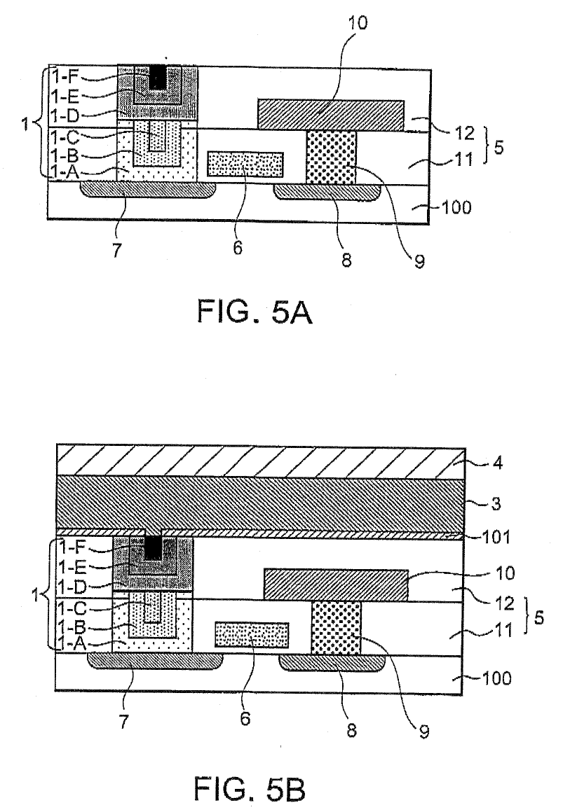

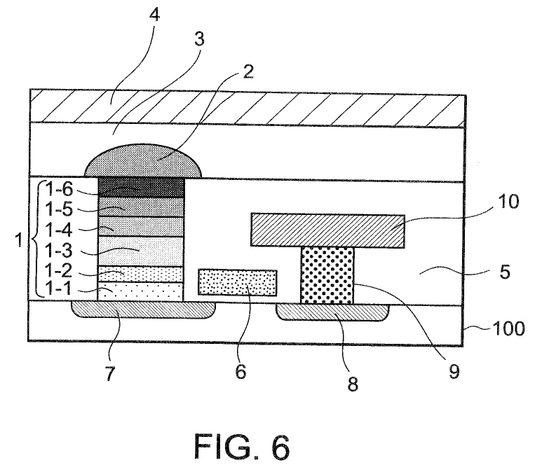

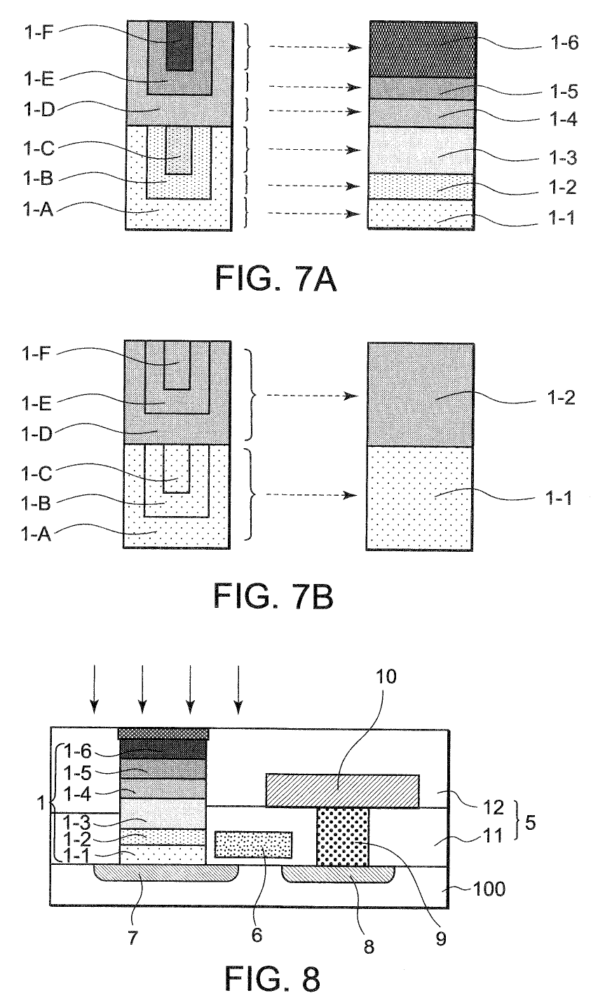

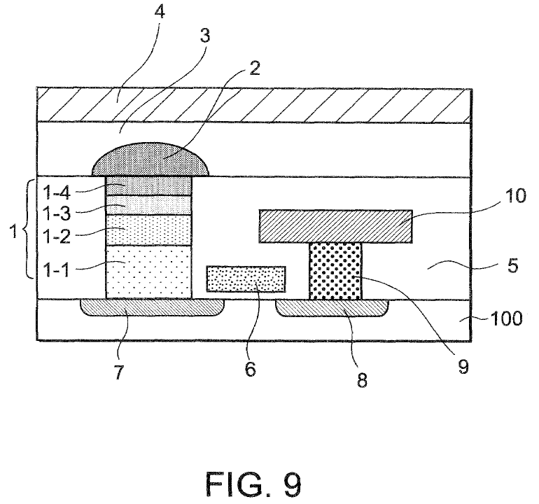

Referring to FIGS. 2 through 9, description will be made about a semiconductor device and a method of manufacturing the same according to the present invention. FIG. 2 shows a circuit diagram of a memory cell of a phase change memory for describing the present invention. FIGS. 3, 4, 5A, 5B, and 6 show sectional views for describing a production process of a phase change memory cell having a heater electrode structure according to the present invention. FIGS. 7A and 7B are views for describing conversion from electrode films formed in a cylindrical shape in a contact hole into heater electrode layers successively laminated in a vertical direction. FIG. 8 shows a sectional view for describing a production process of a phase change memory cell having another heater electrode structure according to the present invention. FIG. 9 shows a sectional view of a phase change memory cell having still another heater electrode structure according to the present invention.

In the memory cell shown in FIG. 2, a variable resistor VR comprising a phase change film has one end connected to a bit line and the other end connected to a drain electrode D of a cell transistor TR. The cell transistor TR has a source electrode S connected to a constant potential wiring and a gate electrode G connected to a word line. The variable resistor VR exhibits a resistance value depending on a crystal state of the phase change film, i.e., a high resistance value in an amorphous state and a low resistance value in a crystalline state. As a memory cell structure, the bit line and the constant potential wiring may be replaced by each other. In this case, one end of the variable resistor VR is connected to the constant potential wiring and the source electrode S of the cell transistor TR is connected to the bit line.

A reading operation of the memory cell is carried out as follows. The word line is activated to turn the cell transistor into an on state. By an electric current flowing through the bit line, a memory state of the memory cell is read. A rewriting operation is carried out as follows. The word line is activated to turn the cell transistor into an on state. By an electric current flowing through the bit line, the crystal state of the phase change film is switched. The phase change film is supplied with a sufficient amount of Joule heat to be melted and thereafter rapidly cooled. Consequently, the phase change film is turned into the amorphous state having a high resistance value. Alternatively, the phase change film is supplied with a smaller amount of Joule heat and then slowly cooled. Consequently, the phase change film is turned into the crystalline state having a low resistance value. The amount of heat to be supplied and a cooling rate are controlled by an electric current value and a length (application time) of a pulse applied to the phase change film.

FIG. 6 shows a sectional view of the phase change memory cell. The memory cell comprises a heater electrode 1, a phase change film 3, an upper electrode 4, an interlayer insulation film 5, a gate electrode 6, a drain diffusion layer region 7, a source diffusion layer region 8, a contact plug 9, and a constant potential wiring 10. The phase change film 3 has a phase change region 2 where a phase is changed. The gate electrode 6 of a cell transistor is connected to a word line. The drain diffusion layer region 7 is connected to the heater electrode 1. The source diffusion layer region 8 is connected via the contact plug 9 to the constant potential wiring 10. The heater electrode 1 comprises six heater electrode layers (1-1, 1-2, . . . , and 1-6) and has one end directly connected to the drain diffusion layer region 7 and the other end connected to the phase change film 3. Further, the phase change film 3 is connected to the upper electrode 4. The upper electrode 4 is connected to a bit line (not shown). The heater electrode 1 is formed so as to directly connect the drain diffusion layer region 7 and the phase change film 3 through one contact hole formed in the interlayer insulation film 5.

The rewriting operation of the phase change memory cell is controlled by an electric voltage value and a length (application time) of a pulse supplied between the upper electrode 4 connected to the bit line and the constant potential wiring 10. By a pulse voltage supplied as mentioned above and current drivability of the cell transistor, a value of a flowing electric current is determined. Considering the amount of heat generation of the heater electrode 1, it is known that the amount of heat generation is proportional to I²Rt. The above-mentioned relationship is represented by:

Amount of Heat Generation of Heater Electrode∝I²Rt

I∝((Amount of Heat Generation)/Rt)^{1/2}

where I represents an electric current flowing through the heater electrode, R, a resistance of the heater electrode, and t, an application time of a pulse.

Specifically, as the resistance of the heater electrode increases, the amount of heat generation increases. Therefore, by increasing the resistance of the heater electrode, it is possible to rewrite data (to cause phase change) with a small amount of electric current. For example, in case where the heater electrode has a specific resistivity not less than 1000 μΩ·cm, a necessary amount of heat generation can be obtained with an electric current corresponding to 70% of that required when the heater electrode has a specific resistivity of 500 μΩ·cm as a typical value. Thus, current supplying capacity can be reduced. As a size of the cell transistor, a width W of the cell transistor can be reduced. Therefore, the memory cell can be formed by the cell transistor of a small size. It is consequently possible to achieve the memory cell of a small size.

The present invention is characterized in that, in order to increase a resistance value of the heater electrode, a material having a high specific resistivity as compared with that generally used in a semiconductor is used as a material of the heater electrode 1. Specifically, TiN (titanium nitride), which is generally obtained by CVD (Chemical Vapor Deposition) using TiCl₄ (titanium tetrachloride) gas as a material, has a specific resistivity of roughly 200 to 500 μΩ·cm. According to the present invention, a material having a higher specific resistivity than the above-mentioned value is used as the heater electrode in an area to be brought into contact with the phase change film. For example, it is required that the specific resistivity is not less than 1000 μΩ·cm. In case of a metallic compound containing a metal, it is required that the specific resistivity is not less than 100 times an inherent specific resistivity of the metal.

For example, in case where the heater electrode 1 comprises TiN deposited by CVD, the specific resistivity of TiN is 200 μΩ·cm. In case where the heater electrode 1 has a diameter of 60 nm and a height of 100 nm, the resistance of the heater electrode 1 is 70.7Ω. On the other hand, in case where the specific resistivity is 1500 μΩ·cm and the heater electrode has a diameter of 60 nm and a height of 100 nm, the resistance of the heater electrode is 530.5Ω. Thus, in the latter case, an electric current value required for obtaining the same amount of heat generation is approximately 36% of that required in the case of the lower specific resistivity. Therefore, rewriting (phase change) can be accomplished with a smaller amount of electric current.

The present invention has a second characteristic that the resistance value of the heater electrode 1 is increased and the specific resistivity thereof is gradually changed. The heater electrode 1 is formed by a plurality of heater electrode layers (six layers in the figure). In a direction from the drain diffusion layer region towards the phase change film (in a vertical direction in the figure), the heater electrode layers (1-1, 1-2, . . . , and 1-6) are successively laminated in this order. In the heater electrode, an area which is desired to most efficiently produce heat is a contact region between the heater electrode and the phase change film. Therefore, the heater electrode layer 1-6 directly beneath the phase change film is given the highest specific resistivity. The heater electrode layer 1-1 as an extracting portion from the drain diffusion layer region has a low specific resistivity value for the purpose of reducing a contact resistance with the diffusion layer region. In the direction from the drain diffusion layer region towards the phase change film (in the vertical direction in the figure), the specific resistivities of the heater electrode layers (1-1, 1-2, . . . , and 1-6) are successively increased in this order.

Comparison will be made between the structure of the present invention in which the specific resistivities of the heater electrode layers are gradually changed (that is, gradually increased in a direction from the lower electrode towards the phase change film) and a related structure (two-layer structure) in which the heater electrode comprises two layers, i.e., an area near the drain diffusion layer and having a low specific resistivity and another area near the phase change film and having a high specific resistivity. In case of the two-layer structure, the area having a high specific resistivity produces heat so as to heat a phase change region to a high temperature. At this time, since the area having a low specific resistivity has a high thermal conductivity, the drain diffusion layer is also heated to a high temperature via the area having a low specific resistivity. On the other hand, the specific resistivity of the heater electrode is gradually changed according to the present invention. In this case, since the heater electrode layer 1-6 directly beneath the phase change film has the highest specific resistivity, an area directly beneath the phase change film is heated to the highest temperature. The heater electrode layers 1-5, 1-4, . . . , and 1-1 are gradually lowered in temperature in this order. Further, the thermal conductivity of the heater electrode layers is low in case where the specific resistivity is high. Therefore, the thermal conductivity of the heater electrode layer 1-5 is low in comparison with the related two-layer structure so that the amount of thermal conduction towards the drain diffusion layer is small and the amount of thermal conduction towards the phase change film is large. Consequently, the temperature of the phase change film is easily increased so as to perform the rewriting operation with a further smaller amount of electric current.

Now, referring to FIGS. 3 through 6, a method of manufacturing the phase change memory having the above-mentioned heater electrode structure will be described. A gate oxide film and a gate electrode film are deposited on a semiconductor substrate 100 to form a gate electrode 6. Next, a drain diffusion layer 7 and a source diffusion layer 8 are formed. Then, a first interlayer insulation film 11 is formed. In the first interlayer insulation film 11 on the source diffusion layer 8, a contact hole is formed and filled with a contact plug 9. A constant potential wiring 10 which is connected to the contact plug 9 is formed. Then, a second interlayer insulation film 12 is deposited. In the first interlayer insulation film 11 and the second interlayer insulation film 12 (hereinafter collectively called an interlayer insulation film 5), a contact hole 13 is formed to reach the drain diffusion layer 7.

The contact hole 13 is filled with, for example, TiN as a heater electrode. In the present invention, film deposition is performed by, for example, MO-CVD (Metal Organic Chemical Vapor Deposition) which can easily form a high-resistance electrode layer. As a material gas, Ti(N(CH₃)₂)₄ (tetrakis(dimethylamino)titanium: hereinafter abbreviated to TDMAT) is used. By MO-CVD, a TiN film is deposited, for example, to the thickness of 10 nm and then subjected to treatment. Specifically, plasma treatment is performed in a N₂—H₂ mixed gas atmosphere to eliminate unnecessary impurities. Further, the deposition and the treatment are repeated a plurality of times to thereby obtain a desired film thickness. By changing deposition conditions, such as a material gas flow rate, the specific resistivity can be increased. In case of MO-CVD, by shortening a treatment time, a high specific resistivity value can be obtained more effectively.

In MO-CVD, a thin film is deposited by using a metal-organic gas and then subjected to the treatment so that the organic gas is sublimated and the thin film is lowered in resistance and stabilized in film quality. In this event, if the treatment time is shortened, the specific resistivity of the deposited metal or metal compound film can be increased. For example, the treatment is generally carried out for 30 seconds. By successively shortening the treatment time stepwise to 25 seconds, 20 seconds, and so on, the specific resistivity can be increased. The treatment time can be shortened to about 3 to 10 seconds. Thus, the film deposition and the treatment are repeated a plurality of times with the treatment time gradually shortened, so that the specific resistivity of the heater electrode can be increased. For example, in case where a TiN film is deposited as an electrode film by MO-CVD, the specific resistivity can be increased to 4500 μΩ·cm.

For example, the heater electrode structure shown in FIG. 4 is formed by depositing a TiN film by MO-CVD using TDMAT as a material gas. First, a TiN film (1-A) is deposited to the thickness of 10 nm and then subjected to the treatment for 30 seconds. Subsequently, a TiN film (1-B) is deposited to the thickness of 10 nm and then subjected to the treatment for 25 seconds. Next, a TiN film (1-C) is deposited to the thickness of 10 nm and then subjected to the treatment for 20 seconds. By gradually shortening the treatment time as mentioned above, specific resistivities of the TiN films (1-A), (1-B), and (1-C) are successively increased in this order. In case where the contact hole has a diameter of 60 nm, the inside of the contact hole is filled with the TiN films (1-A), (1-B), and (1-C). Then, these TiN films are etched back. At this time, an upper surface of the interlayer insulation film 5 and a part of the TiN films in the contact hole are etched. The film deposition and the treatment of the TiN film (1-A) to the TiN film (1-C) and the etch-back are collectively called a first step.

Subsequently, as a second steps at first, a TiN film (1-D) is deposited to the thickness of 10 nm and then subjected to the treatment for 17 seconds. Then, a TiN film (1-E) is deposited to the thickness of 10 nm and then subjected to the treatment for 14 seconds. Next, a TiN film (1-F) is deposited to the thickness of 10 nm and then subjected to the treatment for 11 seconds. By gradually shortening the treatment time, specific resistivities of the TiN films (1-D), (1-E), and (1-F) are successively increased in this order. The contact hole is filled with the deposited TiN films (1-D), (1-E), and (1-F). Planarization is carried out by CMP (Chemical Mechanical Polishing) so that an upper surface of the heater electrode 1 and the upper surface of the interlayer insulation film 5 have the same height (FIG. 5A). The film deposition and the treatment of the TiN film (1-D) to the TiN film (1-F) and CMP are collectively called a second step.

The heater electrode 1 shown in FIG. 5A comprises the TiN films formed in a cylindrical shape in the contact hole, i.e., the TiN films (1-A), (1-D), and (1-C) deposited in the first step and the TiN films (1-D), (1-E), and (1-F) deposited in the second step. Herein, it is assumed that the TiN films in a cylindrical shape are equivalent to flat layers successively laminated in the vertical direction in the figure from the bottom to the top and having the respectively equivalent specific resistivities. FIG. 7A shows correspondence between the cylindrical films and the flat layers as electrode layers. Specifically, in this invention, it is only necessary to consider the amount of heat generation. Therefore, a laminated state only in a center area of the heater electrode 1, where the resistance distribution is largest or widest, must be considered and the influence of a surrounding area is negligible. This means that the cylindrical TiN films have a structure substantially equivalent to a laminated heater shown on the right side in FIG. 7A. Specifically, the heater electrode 1 comprising the TiN films (1-A) to (1-F) in a cylindrical shape is equivalent to a structure comprising a heater electrode layer 1-1 having the lowest specific resistivity and heater electrode layers 1-2, 1-3, 1-4, 1-5, and 1-6 having specific resistivities successively increased in this order from the bottom in the figure.

FIG. 5B shows a structure in which only the TiN film (1-F) is exposed through a hole of an insulation film 101 and is brought into contact with a phase change material of the phase change film 3. In this structure, only a center area having the largest or widest resistance distribution is brought into contact with the phase change material of the phase change film 3. Therefore, this structure is also equivalent to that shown on the right side in FIG. 7A.

For example, the heater electrode layer 1-1 has a specific resistivity and a thickness same as those of the TiN film (1-A). The heater electrode layer 1-2 has a specific resistivity which is a combined specific resistivity of those of the TiN film (1-A) and the TiN film (1-B) and a thickness same as that of the TiN film (1-B). The heater electrode layer 1-3 has a specific resistivity which is a combined specific resistivity of those of the TiN film (1-A), the TiN film (1-B), and the TiN film (1-C) and a thickness which is determined by an etching depth upon the etch-back in the first step. Thus, the TiN films (1-A), (1-B), (1-C), (1-D), (1-E), and (1-F) formed in a cylindrical shape in the contact hole can be replaced by the heater electrode layers 1-1, 1-2, 1-3, 1-4, 1-5, and 1-6, which have the equivalent specific resistivities.

In case where the respective TiN films are deposited in the same condition, i.e., in case where the TiN films (1-A), (1-B), and (1-C) in the first step are deposited in a first condition and the TiN films (1-D), (1-E), and (1-F) in the second step are deposited in a second condition, the specific resistivity is same in each of the first and the second steps so that the TiN films can be converted into two heater electrode layers 1-1 and 1-2, as shown in FIG. 7B. Further, film deposition may be carried out as follows. By typical CVD, the contact hole is at first filled with an electrode layer having a low specific resistivity and the electrode layer is etched back to thereby form a first heater electrode layer 1-1. Then, in a similar manner, heater electrode layers 1-2, 1-3, . . . , and 1-6 are formed with the specific resistivities successively increased in this order. In the manner described above, by repeating such filling of the electrode layer and etching back of the electrode layer, it is possible to form the heater electrode of a multilayer structure shown in FIGS. 6, 8, and 9. In this event, if treatment is carried out, it is preferable to carry out the treatment after etching back of the electrode layer is carried out.

Thus, the heater electrode 1 comprises the electrode films deposited in the contact hole and successively increased in specific resistivity. The deposited electrode films have specific resistivities which are successively increased in the order from the bottom to the top. As shown in FIG. 7A, the heater electrode layers 1-1, 1-2, 1-3, . . . , and 1-6 have specific resistivities successively increased from the bottom to the top in this order. A material of the heater electrode films is not particularly limited but may be any film having a high specific resistivity.

For example, instead of TiN, a high-resistance material, such as TiSiN (titanium silicon nitride), TiAlN (titanium aluminum nitride), C (carbon), CN (carbon nitride), MoN (molybdenum nitride), TaN (tantalum nitride), PtIr (platinum iridium), TiCN (titanium carbon nitride), or TiSiC (titanium silicon carbide) may be used. Further, as the electrode layers, different materials can be used in combination so that the electrode layers have specific resistivities successively increased. Also, film deposition may be carried out using CVD, PVD (Physical Vapor Deposition) such as sputtering, and so on without being limited to MO-CVD.

After the heater electrode layers are formed, the phase change film 3 and the upper electrode 4 are formed, as shown in FIG. 6. The drain diffusion layer 7, the heater electrode 1, the phase change film 3, and the upper electrode 4 are electrically connected through the one contact hole. In the present embodiment, the drain diffusion layer serves as a lower electrode. The upper electrode 4 comprises a conductor film, such as tungsten (W), aluminum (Al), or the like. As a material of the phase change film 3, use may be made of a material including at least two elements selected from germanium (Ge), antimony (Sb), tellurium (Te), selenium (Se), gallium (Ga), and indium (In). For example, the material may be gallium antimonide (GaSb), indium antimonide (InSb), indium selenide (InSe), antimony telluride (Sb₂Te₃), germanium telluride (GeTe), Ge₂Sb₂Te₅, InSbTe, GaSeTe, SnSb₂Te₄, or InSbGe.

The heater electrode of the present invention comprises a plurality of electrode layers having a high specific resistivity. Further, the electrode layers have specific resistivities successively increased in a direction from the drain diffusion layer towards the phase change film. The heater electrode has the maximum specific resistivity in the contact region with the phase change film. With this structure, the heater electrode can efficiently produce heat with a small amount of electric current. Since a rewriting electric current is small, the cell size can be reduced. Thus, a phase change memory excellent in cost performance can be obtained.

FIG. 8 shows a sectional view of a memory cell in another method according to the present invention. The memory cell shown in FIG. 8 has a heater electrode structure in which the specific resistivity is further increased in an electrode layer 1-6 as the uppermost part of a heater electrode 1, i.e., in a contact region with a phase change film 3. After the heater electrode 1 is formed in FIG. 5A, for example, nitrogen is ion-implanted from an upper surface of the heater electrode 1 so as to further increase the specific resistivity of the upper part of the heater electrode 1. At this time, the specific resistivity may be increased in a part of or throughout an entirety of the electrode layer 1-6. In order to increase the specific resistivity of the upper part of the heater electrode, use may be made of a method of implanting nitrogen (N), oxygen (O), carbon (C), or silicon (Si) by ion implantation. Ion implantation is performed with implantation energy on the order of 1 to 30 keV. The implantation depth is different depending on an element to be implanted. Taking this into consideration, implantation is carried out to an optimum depth. After completion of the implantation, heat treatment, for example, RTA (Rapid Thermal Annealing), may be carried out to activate and diffuse the implanted element. Further, plasma treatment may be performed in an oxygen atmosphere or a nitrogen atmosphere to oxidize or nitride the uppermost part of the heater electrode to thereby increase a resistance of the uppermost part of the heater electrode. Furthermore, by performing thermal oxidation or RTO (Rapid Thermal Oxidation), the uppermost part of the heater electrode may be oxidized to thereby increase a resistance thereof. In order to increase the resistance, any of the above-mentioned techniques may be used.

FIG. 9 shows a sectional view of a phase change memory cell having a heater electrode structure in still another method according to the present invention. In a heater electrode 1 shown in FIG. 9, a heater electrode layer 1-1 having a low specific resistivity is particularly increased in thickness. In the present invention, the heater electrodes are formed in one contact hole between the drain diffusion layer 7 and the phase change film 3. Consequently, an aspect ratio of the contact hole is increased. Therefore, the heater electrode layer 1-1 having a low specific resistivity is increased in thickness and, thereafter, heater electrode layers 1-2, 1-3, and 1-4 having desired high specific resistivities are formed. Thus, the thickness of each of the heater electrode layers can be selected depending on the aspect ratio of the contact hole.

Although the number of the heater electrode layers is preferably not less than four, it is possible to obtain a sufficient effect even if the number is not less than three. In this event, a barrier film for preventing reaction with silicon may be provided at a contact surface between the drain diffusion layer and the heater electrode. Even if the barrier film has a high specific resistivity, it is negligible as a substantial resistance value because a film thickness thereof is small. In the foregoing description, the lower electrode is the diffusion layer. However, it is readily understood that, instead of the diffusion layer, a conductive wiring formed in the interlayer insulation film may be used as the lower electrode.

The heater electrode of the present invention is made of a material having a specific resistivity, for example, not less than 1000 μΩ·cm which is higher than that of a metal or a metal compound generally used in a semiconductor device. Further, the specific resistivities of the heater electrode layers are successively increased in a direction from the lower electrode towards the phase change film so that the heater electrode layer in an area to be brought into contact with the phase change film has the maximum specific resistivity. The uppermost heater electrode layer having the maximum specific resistivity enables the phase change film to be efficiently heated to a high temperature. Therefore, a rewriting operation can be efficiently executed with a small amount of rewriting electric current. Since the amount of rewriting electric current is small, the cell size can be reduced. Thus, it is possible to obtain a phase change memory excellent in cost performance.

Although the present invention has been described in connection with a few exemplary embodiments, it will readily be understood that the present invention is not limited to the above-mentioned embodiments but may be modified in various manners without departing from the scope of the present invention and the modifications are encompassed in the present invention. For example, on forming the heater electrode, three TiN films (1-A), (1-B), and (1-C) are firstly deposited in the first step (FIG. 4) in the exemplary embodiment. Thereafter, three TiN films (1-D), (1-E), and (1-F) are furthermore deposited in the second step (FIG. 5a) in the exemplary embodiment. However, the heater electrode may be constituted by only three TiN films (1-A), (1-B), and (1-C) by eliminating the second step on forming the heater electrode.

What is claimed is:

1. A semiconductor device comprising:
an interlayer insulation film formed on a semiconductor substrate to cover a lower electrode;
a heater electrode formed in a contact hole formed in said interlayer insulation film to expose said lower electrode;
a phase change film formed in contact with an upper surface of said heater electrode; and
an upper electrode formed on an upper surface of said phase change film;
said heater electrode having a specific resistivity gradually increased in a direction from said lower electrode towards said phase change film.

2. The semiconductor device as claimed in claim 1, wherein said heater electrode comprises at least three heater electrode layers which are successively laminated and successively increased in specific resistivity in a direction from said lower electrode towards said phase change film in this order.

3. The semiconductor device as claimed in claim 2, wherein each of said heater electrode layers comprises any one of TiN (titanium nitride), TiSiN (titanium silicon nitride), TiAlN (titanium aluminum nitride), C (carbon), CN (carbon nitride), MoN (molybdenum nitride), TaN (tantalum nitride), PtIr (platinum iridium), TiCN (titanium carbon nitride), and TiSiC (titanium silicon carbide).

4. The semiconductor device as claimed in claim 1, wherein said phase change film comprises any one of germanium (Ge), antimony (Sb), tellurium (Te), selenium (Se), gallium (Ga), and indium (In).

5. The semiconductor device as claimed in claim 1, wherein said lower electrode is one of diffusion layers forming a memory cell transistor.

6. The semiconductor device as claimed in claim 5, wherein said upper electrode is connected to a bit line, another diffusion layer of said memory cell transistor being connected to a constant potential wiring.

7. A semiconductor device comprising:
a diffusion layer formed in a semiconductor substrate;
an interlayer insulation film formed on said semiconductor substrate to cover said diffusion layer;
a heater electrode formed in a contact hole formed in said interlayer insulation film to expose said diffusion layer;
a phase change film formed in contact with an upper surface of said heater electrode; and
an upper electrode formed on an upper surface of said phase change film;
said heater electrode being formed in said contact hole for electrically connecting said diffusion layer and said phase change film.

8. The semiconductor device as claimed in claim 7, wherein said heater electrode comprises at least three heater electrode layers which are successively laminated and successively increased in specific resistivity in a direction from said diffusion layer towards said phase change film in this order.

9. A method of manufacturing a semiconductor device, comprising the steps of:
depositing an interlayer insulation film to cover a lower electrode;
forming a contact hole in said interlayer insulation film to expose said lower electrode;
forming a heater electrode in said contact;
depositing a phase change film in contact with an upper surface of said heater electrode; and
forming an upper electrode on an upper surface of said phase change film;
wherein said step of forming said heater electrode comprises the step of forming at least three heater electrode layers which are successively laminated in said contact hole and successively increased in specific resistivity in a direction from said lower electrode towards said phase change film in this order.

10. The method as claimed in claim 9, wherein a top one of said heater electrode layers has the specific resistivity equal to or greater than 1000 μΩ·cm.

11. The method as claimed in claim 9 wherein a top one of said heater electrode layers comprises a metal compound containing a metal, said metal compound having the specific resistivity equal to or greater than 100 times that of said metal.

12. The method as claimed in claim 9, wherein each of said heater electrode layers comprises any one of TiN (titanium nitride), TiSiN (titanium silicon nitride), TiAlN (titanium aluminum nitride), C (carbon), CN (carbon nitride), MoN (molybdenum nitride), TaN (tantalum nitride), PtIr (platinum iridium), TiCN (titanium carbon nitride), and TiSiC (titanium silicon carbide).

13. The method as claimed in claim 9, wherein said step of forming said heater electrode layers is executed using MOCVD (Metal Organic Chemical Vapor Deposition).

14. The method as claimed in claim 13, wherein said step of forming said heater electrode further comprises the step of carrying out treatment for each of said heater electrode layers after each of said heater electrode layers is formed by using said MOCVD.

15. The method as claimed in claim 14, wherein the specific resistivity of each of said heater electrode layers is changed by controlling a treatment time in said step of carrying out said treatment for each of said heater electrode layers.

16. The method as claimed in claim 9, further comprising the step of further increasing an upper surface of a top one of said heater electrode layers in specific resistivity by ion-implantation of any one of oxygen, nitrogen, carbon, and silicon.

17. The method as claimed in claim 11, further comprising the step of further increasing an upper surface of a top one of said heater electrode layers in specific resistivity by using any one of thermal oxidation, plasma oxidation, and plasma nitridation.
